(19) United States
(12) Patent Application Publication
(10) Pub. No.: US 2025/0280667 A1
(43) Pub. Date: Sep. 4, 2025

(54) Display Device

(71) Applicant: LG Display Co., Ltd., Seoul (KR)

(72) Inventors: Bongjun Kim, Namyangju-si (KR); WooJung Byun, Goyang-si (KR); Jongmoon Byun, Goyang-si (KR)

(21) Appl. No.: 18/999,367

(22) Filed: Dec. 23, 2024

(30) Foreign Application Priority Data
Feb. 29, 2024 (KR) 10-2024-0030141

(51) Int. Cl. H10K 59/124; H10K 59/121; H10K 59/122; H10K 59/38; H10K 102/00

(52) U.S. Cl. CPC H10K 59/124; H10K 59/1213; H10K 59/122; H10K 59/38; H10K 2102/351

(57) ABSTRACT

A display device includes: a substrate on which subpixels that each include a light-emitting area and a non-light-emitting area that surrounds the light-emitting area are disposed; a transistor in the non-light-emitting area on the substrate; an overcoating layer in the light-emitting area and the non-light-emitting area on the transistor and including a groove in the non-light-emitting area along an outer periphery of the light-emitting area; a first electrode in the light-emitting area on the overcoating layer; a bank in the non-light-emitting area on the overcoating layer and spaced apart from the first electrode; an organic layer on the first electrode and the bank; and a second electrode on the organic layer and overlapping the first electrode and the groove, in which a thickness of the bank in the groove on the overcoating layer is smaller than a thickness of the bank disposed in the remaining part.

### CROSS-REFERENCE TO RELATED APPLICATION

This application claims the priority of Republic of Korea Patent Application No. 10-2024-0030141 filed on Feb. 29, 2024, which is hereby incorporated by reference in its entirety.

### BACKGROUND

### Field

The present disclosure relates to a display device, and more particularly, to a display device capable of improving light extraction efficiency and minimizing or at least reducing a moisture penetration defect.

### Description of the Related Art

Recently, display devices, which visually display electrical information signals, are being rapidly developed in accordance with the full-fledged entry into the information era. Various studies are being continuously conducted to develop a variety of display devices which are thin and lightweight, consume low power, and have improved performance.

Among the various display devices, a self-luminous display device refers to a display device that autonomously emits light. Unlike a liquid crystal display device, the self-luminous display device does not require a separate light source and thus may be manufactured as a lightweight, thin display device. In addition, the self-luminous light-emitting display device is advantageous in terms of power consumption because the self-luminous light-emitting display device operates at a low voltage. Further, the self-luminous light-emitting display device is expected to be adopted in various fields because the self-luminous light-emitting display device is also excellent in implementation of colors, response speeds, viewing angles, and contrast ratios (CRs).

### SUMMARY

An object to be achieved by the present disclosure is to provide a high-efficiency, low-power consumption display device capable of improving luminous efficiency of a light-emitting element.

Another object to be achieved by the present disclosure is to provide a display device capable of minimizing or at least reducing a moisture penetration defect.

Objects of the present disclosure are not limited to the above-mentioned objects, and other objects, which are not mentioned above, can be clearly understood by those skilled in the art from the following descriptions.

A display device according to an embodiment of the present disclosure includes: a substrate on which a plurality of subpixels each including a light-emitting area and a non-light-emitting area configured to surround the light-emitting area is disposed; a transistor disposed in the non-light-emitting area on the substrate; an overcoating layer disposed in the light-emitting area and the non-light-emitting area on the transistor and including a groove disposed in the non-light-emitting area along an outer periphery of the light-emitting area; a first electrode disposed in the light-emitting area on the overcoating layer; a bank disposed in the non-light-emitting area on the overcoating layer and disposed to be spaced apart from the first electrode; an organic layer disposed on the first electrode and the bank; and a second electrode disposed on the organic layer and configured to overlap the first electrode and the groove, in which a thickness of the bank disposed in the groove on the overcoating layer is smaller than a thickness of the bank disposed in the remaining part.

A display device according to another embodiment of the present disclosure includes: a substrate on which a plurality of subpixels each including a light-emitting area is disposed; an overcoating layer disposed on the substrate and including a groove disposed along an outer periphery of a light-emitting area of each of the plurality of subpixels; a first electrode disposed in the light-emitting area on the overcoating layer; a bank including a first bank disposed on the overcoating layer and spaced apart from the first electrode, and a second bank disposed in the groove and having a smaller thickness than the first bank; an organic layer disposed on the first electrode and the bank; and a second electrode disposed on the organic layer and configured to overlap the first electrode and the groove.

Other detailed matters of the exemplary embodiments are included in the detailed description and the drawings.

According to the present disclosure, it is possible to improve the light extraction efficiency of the bottom-emission type display device and reduce power consumption.

According to the present disclosure, it is possible to minimize a moisture penetration defect caused by an irregular concave-convex shape of the groove of the overcoating layer.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a top plan view of a display device according to an embodiment of the present disclosure;

FIGS. 2A and 2B are enlarged top plan views of area A in FIG. 1 according to an embodiment of the present disclosure;

FIG. 3 is a cross-sectional view of the display device taken along line B-B′ in FIG. 2A according to an embodiment of the present disclosure;

FIG. 4 is a cross-sectional view of the display device taken along line C-C′ in FIG. 2A according to an embodiment of the present disclosure; and

FIGS. 5A to 5F are process flowcharts for explaining a process of manufacturing the display device according to an embodiment of the present specification.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, comprising' used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

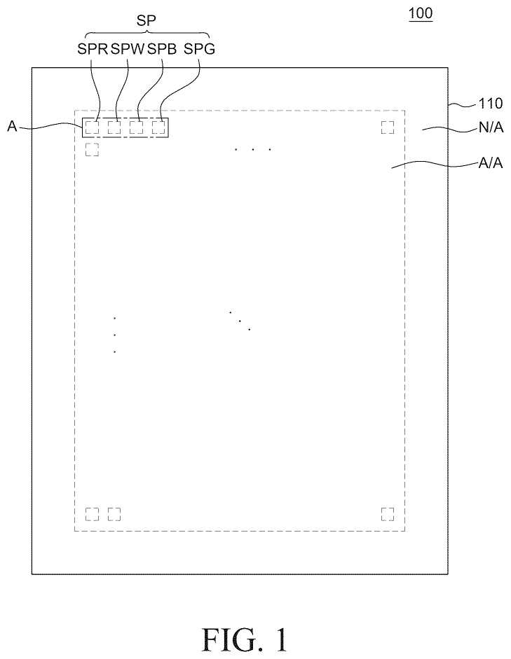

FIG. 1 is a top plan view of a display device according to an embodiment of the present disclosure.

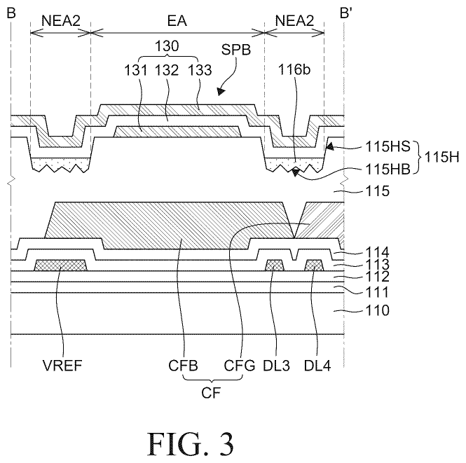

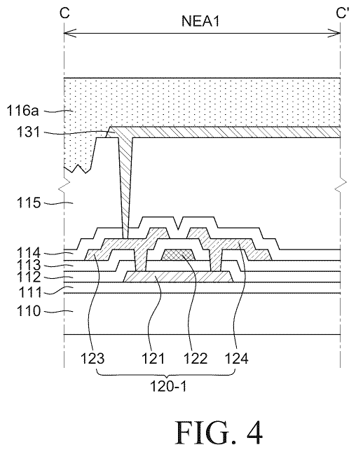

With reference to FIG. 1, the display device 100 includes the substrate 110. The display device 100 according to the embodiment of the present disclosure may be configured as a bottom-emission type display device. The bottom-emission type display device emits light to a rear surface of the substrate 110 configured as a transparent substrate. In the case of the bottom-emission type display device, a first electrode of a light-emitting element may be made of a transparent conductive material and a second electrode may be made of a metallic material with high reflectance in order to allow light emitted from the light-emitting element to propagate toward a lower side of the transparent substrate. However, this configuration will be described below with reference to FIGS. 3 and 4.

The substrate 110 is configured to support and protect several constituent elements of the display device 100. The substrate 110 may be made of an insulating material having transparency to allow the light emitted from the light-emitting element to propagate downward. For example, the substrate 110 may be made of glass or a plastic material having flexibility. In the case in which the substrate 110 is made of a plastic material, the substrate 110 may be made of polyimide (PI), for example. However, the present disclosure is not limited thereto.

The substrate 110 includes a display area A/A and a non-display area N/A.

The display area A/A refers to an area of the display device 100 in which images are displayed. Various display elements and various driving elements for operating the display elements may be disposed in the display area A/A. For example, the display element may include a light-emitting element including a first electrode, an organic layer, and a second electrode. In addition, various driving elements such as transistors, capacitors, lines, and the like, which are configured to operate the display elements, may be disposed in the display area A/A.

A plurality of subpixels SP may be included in the display area A/A. The subpixel SP is a minimum unit that constitutes a screen. The plurality of subpixels SP may each include a light-emitting element and a drive circuit. The plurality of subpixels SP may be disposed in a plurality of rows and a plurality of columns.

The drive circuit of the subpixel SP is a circuit for controlling an operation of the light-emitting element. For example, the drive circuit may include a transistor and a capacitor. However, the present disclosure is not limited thereto.

The non-display area N/A refers to an area in which no image is displayed. Various constituent elements for operating the plurality of subpixels SP disposed in the display area A/A may be disposed in the non-display area N/A. For example, drive integrated circuits (Ics), flexible films, and the like, which are configured to supply signals for operating the plurality of subpixels SP, may also be disposed.

As illustrated in FIG. 1, the non-display area N/A may be an area that surrounds the display area A/A. However, the present disclosure is not limited thereto. For example, the non-display area N/A may be an area extending from the display area A/A.

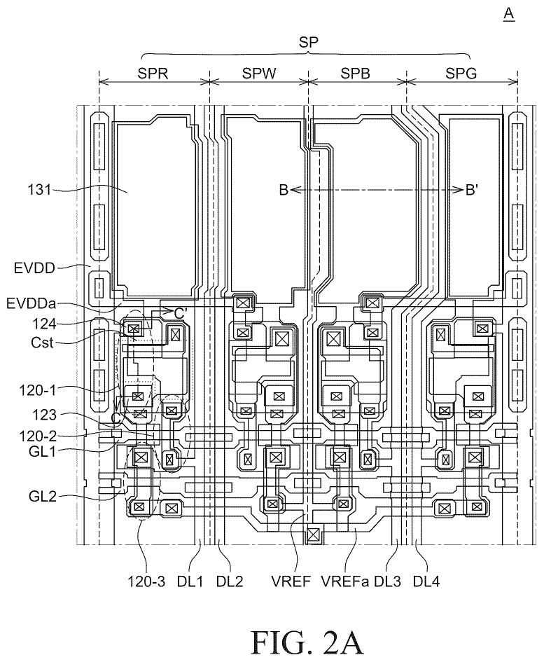

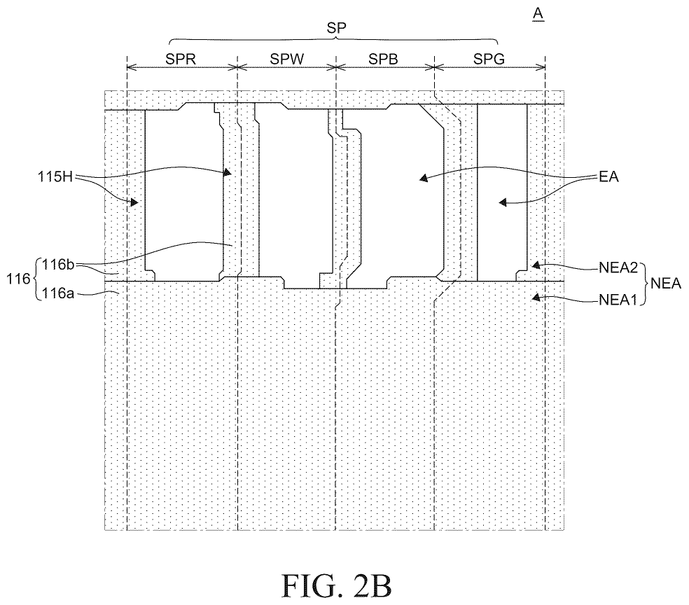

FIGS. 2A and 2B are enlarged top plan views of area A in FIG. 1 according to an embodiment of the present disclosure. FIG. 2A is a view for explaining planar structures of the plurality of subpixels. For convenience of description, FIG. 2B illustrates a bank 116 among various constituent elements of the display device 100.

The plurality of subpixels SP may include first to fourth subpixels configured to emit lights of different wavelengths. The first to fourth subpixels configured to emit light of different wavelengths may each include the light-emitting element and the pixel circuit and independently emit lights. For example, the plurality of subpixels SP may include a red subpixel SPR that is a first subpixel, a white subpixel SPW that is a second subpixel, a blue subpixel SPB that is a third subpixel, and a green subpixel SPG that is a fourth subpixel. However, the present disclosure is not limited thereto.

With reference to FIG. 2A, for example, the plurality of subpixels SP may be disposed in a stripe manner in which the red subpixel SPR, the white subpixel SPW, the blue subpixel SPB, and the green subpixel SPG, which emit lights of different colors, are arranged in one direction. However, the present disclosure is not limited thereto.

With reference to FIG. 2A, a first transistor 120-1, a second transistor 120-2, a third transistor 120-3, a storage capacitor Cst, a plurality of gate lines GL1 and GL2, a plurality of data lines DL1, DL2, DL3, and DL4, a high-potential power line EVDD, an auxiliary high-potential power line EVDDa, a reference line VREF, an auxiliary reference line VREFa, and a light-emitting element 130 are disposed in each of the plurality of subpixels SP of the display device 100 according to the embodiment of the present disclosure.

he plurality of data lines DL1, DL2, DL3, and DL4, the high-potential power line EVDD, and the reference line VREF are disposed between the plurality of subpixels SP. The plurality of gate lines GL1 and GL2, the auxiliary high-potential power line EVDDa, and the auxiliary reference line VREFa are disposed to traverse the plurality of subpixels SP. Further, the first transistor 120-1, the second transistor 120-2, the third transistor 120-3, the storage capacitor Cst, and the light-emitting element 130 are disposed in each of the plurality of subpixels SP.

The first transistor 120-1, the second transistor 120-2, and the third transistor 120-3 each include an active layer 121, a gate electrode 122, a source electrode 123, and a drain electrode 124. The light-emitting element 130 includes a first electrode 131, an organic layer 132, and a second electrode 133.

The plurality of gate lines GL1 and GL2 and the plurality of data lines DL1, DL2, DL3, and DL4 may be disposed to intersect one another and define the plurality of subpixels SP.

The plurality of gate lines GL1 and GL2 includes a first gate line GL1 and a second gate line GL2. The first gate line GL1 and the second gate line GL2 extends in one direction. The first gate line GL1 and the second gate line GL2 may extend in one direction and be disposed to traverse all the red subpixel SPR, the white subpixel SPW, the blue subpixel SPB, and the green subpixel SPG of the plurality of subpixels SP. For example, the first gate line GL1 and the second gate line GL2 may be connected to the first transistor 120-1 and the second transistor 120-2 of each of the plurality of subpixels SP. Therefore, the first gate line GL1 and the second gate line GL2 may supply scan signals to each of the plurality of subpixels SP.

The plurality of data lines DL1, DL2, DL3, and DL4 includes a first data line DL1, a second data line DL2, a third data line DL3, and a fourth data line DL4. The plurality of data lines DL1, DL2, DL3, and DL4 extends in directions intersecting the plurality of gate lines GL1 and GL2. The plurality of data lines DL1, DL2, DL3, and DL4 is disposed between the plurality of subpixels SP. The plurality of data lines DL1, DL2, DL3, and DL4 may be connected while respectively corresponding to the plurality of subpixels SP. Therefore, the plurality of data lines DL1, DL2, DL3, and DL4 may supply data voltages to the plurality of subpixels SP.

The high-potential power line EVDD is disposed between the plurality of subpixels SP and extends in the same direction as the plurality of data lines DL1, DL2, DL3, and DL4. The high-potential power lines EVDD may be disposed at two opposite edges of the plurality of subpixels SP. In this case, the red subpixel SPR and the green subpixel SPG adjacent to the high-potential power line EVDD may be connected directly to the high-potential power line EVDD, and the white subpixel SPW and the blue subpixel SPB may be connected to the high-potential power line EVDD through the auxiliary high-potential power line EVDDa. The high-potential power line EVDD may transmit a high-potential power voltage for operating the first transistor 120-1 of each of the plurality of subpixels SP.

The reference line VREF is disposed between the plurality of subpixels SP and extends in the same direction as the plurality of data lines DL1, DL2, DL3, and DL4. The reference line VREF may transmit a reference voltage to each of the plurality of subpixels SP. For example, the white subpixel SPW and the blue subpixel SPB adjacent to the reference line VREF may be connected directly to the reference line VREF, and the red subpixel SPR and the green subpixel SPG may be connected to the reference line VREF through the auxiliary reference line VREFa.

In each of the plurality of subpixels SP, the first transistor 120-1, the second transistor 120-2, the third transistor 120-3, the storage capacitor Cst, and the light-emitting element 130 are disposed between the plurality of data lines DL1, DL2, DL3, and DL4 and the gate lines GL1 and GL2.

The first transistor 120-1 is a transistor configured to supply a drive current to the light-emitting element 130. The first transistor 120-1 may be turned on and control the drive current flowing to the light-emitting element 130. Therefore, the first transistor 120-1, which controls the drive current, may be referred to as a driving transistor.

The second transistor 120-2 is a transistor configured to transmit the data voltage to the gate electrode of the first transistor 120-1. The second transistor 120-2 may be turned on by the scan signal of the gate lines GL1 and GL2. Further, the data voltages of the data lines DL1, DL2, DL3, and DL4 may be transmitted to the gate electrode of the first transistor 120-1 through the turned-on second transistor 120-2. Therefore, the second transistor 120-2 may be referred to as a switching transistor.

The third transistor 120-3 is a transistor configured to compensate for a threshold voltage of the first transistor 120-1. The third transistor 120-3 is connected between the source electrode of the first transistor 120-1 and the reference line VREF. The third transistor 120-3 may be turned on, transmit the reference voltage to the source electrode of the first transistor 120-1, and sense a threshold voltage of the first transistor 120-1. Therefore, the third transistor 120-3, which senses the properties of the first transistor 120-1, may be referred to as a sensing transistor.

An upper electrode of the storage capacitor Cst may be connected to the gate electrode of the first transistor 120-1, and a lower electrode of the storage capacitor Cst may be connected to the first electrode 131 of the light-emitting element 130. The storage capacitor Cst may store a potential difference between the gate electrode and the source electrode of the first transistor 120-1 while the light-emitting element 130 emits light, such that a constant electric current may be supplied to the light-emitting element 130.

With reference to FIG. 2B, each of the plurality of subpixels SP includes a light-emitting area EA, and a non-light-emitting area NEA configured to surround the light-emitting area EA.

The light-emitting area EA may be an area in which the first electrode 131 of the light-emitting element 130 is disposed in each of the plurality of subpixels SP. The light-emitting area EA may correspond to an area of the subpixel SP exposed by the bank 116. However, the present disclosure is not limited thereto.

The non-light-emitting area NEA may be an area in which the first electrode 131 is not disposed in each of the plurality of subpixels SP. The non-light-emitting area NEA may include a first non-light-emitting area NEA1 and a second non-light-emitting area NEA2.

The first non-light-emitting area NEA1 may be an area in which the first transistor 120-1, the second transistor 120-2, the third transistor 120-3, and the storage capacitor Cst are disposed in each of the plurality of subpixels SP. In this case, the area, in which the first transistor 120-1, the second transistor 120-2, the third transistor 120-3, and the storage capacitor Cst are disposed, may be a portion, where constituent elements for operating the light-emitting area EA are disposed, and thus also referred to as a circuit area. However, the present disclosure is not limited thereto.

The second non-light-emitting area NEA2 may be an area between the plurality of subpixels SP. The plurality of data lines DL1, DL2, DL3, and DL4, the high-potential power line EVDD, and the reference line VREF may be disposed in the area between the plurality of subpixels SP and configured not to substantially emit light to reduce a color mixture between the plurality of subpixels SP. However, the present disclosure is not limited thereto.

Meanwhile, with reference to FIG. 2B, the light-emitting area EA may be defined as an area exposed from the bank 116, and the non-light-emitting area NEA may be defined as an area in which the bank 116 is disposed. However, the present disclosure is not limited thereto.

In addition, with reference to FIG. 2B, a first bank 116a is disposed in the first non-light-emitting area NEA1, and a second bank 116b is disposed in the second non-light-emitting area NEA2. The first bank 116a and the second bank 116b may be simultaneously formed, made of the same material, and disposed with different thicknesses. However, a specific description of the first bank 116a and the second bank 116b will be described below with reference to FIGS. 3 and 4.

FIG. 3 is a cross-sectional view of the display device taken along line B-B′ in FIG. 2A according to an embodiment of the present disclosure. FIG. 4 is a cross-sectional view of the display device taken along line C-C′ in FIG. 2A according to an embodiment of the present disclosure. FIG. 3 is a cross-sectional view illustrating the light-emitting area and the second non-light-emitting area, and FIG. 4 is a cross-sectional view illustrating the first non-light-emitting area.

With reference to FIGS. 3 and 4, the substrate 110, a buffer layer 111, a gate insulation layer 112, an interlayer insulation layer 113, the first transistor 120-1, a passivation layer 114, an overcoating layer 115, the first electrode 131, the organic layer 132, the second electrode 133, and the bank 116 are disposed in each of the plurality of subpixels SP of the display device 100.

The buffer layer 111 is disposed on the substrate 110. The buffer layer 111 may serve to increase bonding forces between the substrate 110 and layers formed on the buffer layer 111 and block a leak of an alkaline material from the substrate 110. The buffer layer 111 may be configured as a single layer made of silicon nitride (SiNx) or silicon oxide (SiOx) or a multilayer made of silicon nitride (SiNx) or silicon oxide (SiOx). However, the present disclosure is not limited thereto. In one embodiment, the buffer layer 111 is not an essential constituent element. The buffer layer 111 may be eliminated depending on the type and material of the substrate 110, the structure and type of transistor 120, and the like.

The transistor 120 is disposed on the buffer layer 111 in each of the plurality of subpixels SP. The transistor 120 may be used as a driving element for operating the light-emitting element 130 in the display area A/A. The transistor 120 includes the active layer 121, the gate electrode 122, the source electrode 123, and the drain electrode 124.

Meanwhile, the transistor 120 illustrated in FIG. 4 is the first transistor 120-1 that is the driving transistor. The gate electrode 122 is a thin-film transistor with a top-gate structure disposed on the active layer 121. However, the present disclosure is not limited thereto. The first transistor 120-1 may be implemented as a transistor having a bottom-gate structure.

Hereinafter, in order to omit a repeated description, a configuration of the transistor 120 will be described with reference to the first transistor 120-1, as an example, among various transistors 120 disposed in the plurality of subpixels SP.

The active layer 121 is disposed on the buffer layer 111. The active layer 121 is an area in which a channel is formed when the transistor 120 operates. The active layer 121 may be made of an oxide semiconductor. The active layer 121 may be made of amorphous silicon (a-Si), polycrystalline silicon (poly-Si), an organic semiconductor, or the like.

The gate insulation layer 112 is disposed on the active layer 121. The gate insulation layer 112 is a layer for electrically insulating the active layer 121 and the gate electrode 122. The gate insulation layer 112 may be made of an insulating material. For example, the gate insulation layer 112 may be configured as a single layer made of silicon nitride (SiNx) or silicon oxide (SiOx) that is an inorganic material. Alternatively, the gate insulation layer 112 may be configured as a multilayer made of silicon nitride (SiNx) or silicon oxide (SiOx). However, the present disclosure is not limited thereto.

The gate insulation layer 112 has contact holes through which the source electrode 123 and the drain electrode 124 are in contact with a source area and a drain area of the active layer 121, respectively. As illustrated in FIG. 4, the gate insulation layer 112 may be formed over the entire surface of the substrate 110 or patterned to have the same width as the gate electrode 122. However, the present disclosure is not limited thereto.

The gate electrode 122 is disposed on the gate insulation layer 112. The gate electrode 122 is disposed on the gate insulation layer 112 and overlaps the channel area of the active layer 121. The gate electrode 122 may be made of any one of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. Alternatively, the gate electrode 122 may be configured as a multilayer made of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. However, the present disclosure is not limited thereto.

The interlayer insulation layer 113 is disposed on the gate electrode 122. The interlayer insulation layer 113 may be configured as a single layer made of silicon nitride (SiNx) or silicon oxide (SiOx) that is an inorganic material. Alternatively, the interlayer insulation layer 113 may be configured as a multilayer made of silicon nitride (SiNx) or silicon oxide (SiOx). However, the present disclosure is not limited thereto. The interlayer insulation layer 113 has contact holes through which the source electrode 123 and the drain electrode 124 are in contact with the source area and the drain area of the active layer 121, respectively.

The source electrode 123 and the drain electrode 124 are disposed on the interlayer insulation layer 113. The source electrode 123 and the drain electrode 124 are disposed on the same layer and spaced apart from each other. The source electrode 123 and the drain electrode 124 are electrically connected to the active layer 121 through the contact holes of the gate insulation layer 112 and the contact holes of the interlayer insulation layer 113. The source electrode 123 and the drain electrode 124 may each be made of any one of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. Alternatively, the source electrode 123 and the drain electrode 124 may each be configured as a multilayer made of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. However, the present disclosure is not limited thereto.

FIG. 4 illustrates only the first transistor 120-1 that is the driving transistor among various transistors 120 included in the display device 100. However, other transistors, such as the switching transistor, may be disposed in each of the plurality of subpixels SP.

The passivation layer 114 is disposed on the first transistor 120-1 and covers the first transistor 120-1. The passivation layer 114 is disposed on the source electrode 123 and the drain electrode 124. For example, the passivation layer 114 may be configured as a single layer made of silicon nitride (SiNx) or silicon oxide (SiOx) or configured as a multilayer made of silicon nitride (SiNx) or silicon oxide (SiOx). However, the present disclosure is not limited thereto.

A plurality of color filters CF are disposed on the passivation layer 114. Each color filter CF absorbs light in a particular wavelength band emitted from the light-emitting element 130 and transmits light in the remaining wavelength band, thereby improving color reproducibility of the display device 100.

The plurality of color filters CF are disposed to correspond to the light-emitting areas EA of the plurality of subpixels SP. In this case, the plurality of color filters CF are disposed to correspond to the light-emitting areas EA and spaced apart from the plurality of transistors 120. Therefore, a configuration, which is disposed below the plurality of color filters CF and hinders the propagation of light emitted from the light-emitting element 130, may be minimized, such that the light emitted from the light-emitting element 130 may smoothly propagate to the outside of the display device 100 through the plurality of color filters CF and the substrate 110.

The plurality of color filters CF are disposed to respectively correspond to the plurality of subpixels SP that are configured to emit light of different colors. For example, the plurality of color filters CF may include a red color filter disposed to correspond to the red subpixel SPR, a blue color filter CFB disposed to correspond to the blue subpixel SPB, and a green color filter CFG disposed to correspond to the green subpixel SPG. However, the present disclosure is not limited thereto.

The overcoating layer 115 is disposed on the passivation layer 114 and the color filter CF. The overcoating layer 115 is an insulation layer configured to protect the transistor 120 and the color filter CF and planarize upper portions of the transistor 120 and the color filter CF. The overcoating layer 115 has a contact hole through which the source electrode 123 of the transistor 120 is exposed. FIG. 4 illustrates that the contact hole is formed in the overcoating layer 115 in order to expose the source electrode 123. However, the present disclosure is not limited thereto. For example, the overcoating layer 115 may have a contact hole through which the drain electrode 124 is exposed.

The overcoating layer 115 may be made of any one of acrylic resin, epoxy resin, phenolic resin, polyamide-based resin, polyimide-based resin, unsaturated polyester-based resin, polyphenylene-based resin, polyphenylene sulfide-based resin, benzocyclobutene, and photoresist. However, the present disclosure is not limited thereto.

With reference to FIGS. 2B and 3, the overcoating layer 115 includes a groove 115H. The groove 115H may be a portion made by removing a part of a top surface of the overcoating layer 115. The groove 115H is disposed along an outer periphery of the light-emitting area EA of each of the plurality of subpixels SP. The grooves 115H are respectively disposed at two opposite sides of the plurality of subpixels SP configured to emit lights of different colors.

With reference to FIG. 3, the groove 115H includes a side surface 115HS having an inclination, and a bottom surface 115HB surrounded by the side surface 115HS.

The side surface 115HS of the groove 115H may have an inclination. The second electrode of the light-emitting element is disposed on the side surface 115HS of the groove 115H. In this case, the second electrode disposed on the side surface of the groove may reflect lights, which are emitted to the side surface of the light-emitting element among the lights emitted from the organic layer of the light-emitting element, by the shape of the inclined side surface, and extract the lights to the lower side of the display device.

The bottom surface 115HB of the groove 115H may be a portion surrounded by the side surface 115HS. For example, the groove may be configured only by the side surface. A bottom surface may be included in the groove in consideration of a space in which the second electrode for reflecting light is to be disposed.

Meanwhile, with reference to FIG. 3, the bottom surface 115HB of the groove 115H may have a shape having a concave-convex portion formed on the surface thereof. For example, the groove 115H may be formed by removing a part of the surface of the overcoating layer 115 by performing ashing on the surface of the overcoating layer 115. In this case, on the surface of the groove 115H that is in contact with an etching solution, the bottom surface 115HB may be an area that requires higher straightness during an ashing process than the side surface 115HS of the groove 115H with an inclined shape. Therefore, the bottom surface 115HB may be more severely damaged by the ashing process than the side surface 115H of the groove 115H and thus have a larger concave-convex portion of the surface than the side surface 115H of the groove 115H. However, the present disclosure is not limited thereto.

Meanwhile, the groove 115H of the overcoating layer 115 may be disposed to surround even the constituent elements disposed on the same layer as the first electrode 131. That is, the groove 115H may be disposed even in the first non-light-emitting area NEA1. However, because the first non-light-emitting area NEA1 is an area in which the organic layer 132 is not disposed and light is not emitted, the first bank 116a, instead of the second bank 116b, disposed in the groove 115H disposed in the first non-light-emitting area NEA1.

The light-emitting element 130 is disposed on the overcoating layer 115 in each of the plurality of subpixels SP.

The light-emitting element 130 includes the first electrode 131 electrically connected to the source electrode 123 of the transistor 120, the organic layer 132 disposed on the first electrode 131, and the second electrode 133 formed on the organic layer 132.

The first electrode 131 is disposed to correspond to each of the plurality of subpixels SP. The first electrode 131 is disposed on the overcoating layer 115. The first electrode 131 may be disposed on a flat surface on the overcoating layer 115 on which the groove 115H is not disposed.

The first electrode 131 may be an anode of the light-emitting element 130. As illustrated in FIG. 4, the first electrode 131 may be electrically connected to the source electrode 123 of the transistor 120 through a contact hole formed in the overcoating layer 115. However, the first electrode 131 may be electrically connected to the drain electrode 124 of the transistor 120 depending on the type of transistor 120, a method of designing the drive circuit, and the like.

The first electrode 131 is a constituent element for supplying positive holes to the organic layer 132, and the first electrode 131 may be made of an electrically conductive material having a high work function. The first electrode 131 may be a transparent conductive layer made of a transparent conductive oxide (TCO). For example, the first electrode 131 may be made of one or more materials selected from transparent conductive oxides such as indium-tin-oxide (ITO), indium-zinc-oxide (IZO), indium-tin-zinc-oxide (ITZO), tin oxide (SnO2), zinc oxide (ZnO), indium-copper-oxide (ICO), and aluminum: zinc oxide (Al:ZnO, AZO). However, the present disclosure is not limited thereto. Because the display device 100 according to the embodiment of the present disclosure is a bottom-emission type display device, the first electrode 131 may be configured only by a transparent conductive layer. However, the present disclosure is not limited thereto.

The bank 116 is disposed on the overcoating layer 115. The bank 116 is an insulation layer for distinguishing the adjacent subpixels SP. The bank 116 may define an opening area spaced apart from the first electrode 131 and configured to expose the first electrode 131.

The bank 116 may be made of an inorganic material. For example, the bank 116 may be configured as a single layer made of silicon nitride (SiNx) or silicon oxide (SiOx) or configured as a multilayer made of silicon nitride (SiNx) or silicon oxide (SiOx). However, the present disclosure is not limited thereto. The bank 116 may be made of an organic material.

With reference to FIGS. 2B to 4, the bank 116 includes the first bank 116a and the second bank 116b.

The first bank 116a is disposed in the first non-light-emitting area NEA1. The first bank 116a may be disposed above the circuit element, such as the transistor 120, for operating the light-emitting element 130.

The second bank 116b is disposed in the second non-light-emitting area NEA2. The second bank 116b is disposed in the groove 115H of the overcoating layer 115. Therefore, the second bank 116b may be configured to cover the shape with the concave-convex portion of the bottom surface 115HB of the groove 115H. For example, roughness of a bottom surface of the second bank 116b, which corresponds to the concave-convex shape of the bottom surface 115HB of the groove 115H, may be higher than roughness of a top surface of the second bank 116b. In addition, because the groove 115H has a shape surrounded by the inclined side surface 115HS, a width of the top surface of the second bank 116b may be larger than a width of the bottom surface of the second bank 116b.

A thickness of the second bank 116b may be smaller than a thickness of the first bank 116a. Therefore, the second bank 116b may expose the side surface 115HS of the groove 115H. The second bank 116b may expose an upper side of the side surface 115HS of the groove 115H. Further, the organic layer 132 and the second electrode 133 may be disposed on the side surface 115HS of the groove 115H exposed from the second bank 116b.

Meanwhile, the first bank 116a and the second bank 116b may be simultaneously formed and made of the same material. Therefore, no interface may be formed between the first bank 116a and the second bank 116b. The first bank 116a and the second bank 116b may be disposed to be connected to each other. However, the first bank 116a and the second bank 116b may be connected while defining a stepped portion formed by a difference in thickness between the first bank 116a and the second bank 116b. For example, the first bank 116a and the second bank 116b may be simultaneously formed and made of the same material by using a halftone mask and disposed with different thicknesses. However, the present disclosure is not limited thereto.

In this case, during a process of manufacturing the bank 116, an area, in which the first bank 116a is formed by using a full-tone mask, may be referred to as a full-tone bank area, and an area, in which the second bank 116b is formed by using a halftone mask, may be referred to as a halftone bank area. However, the present disclosure is not limited thereto.

With reference to FIG. 2B, the bank 116 may include an opening area corresponding to the light-emitting area EA of each of the plurality of subpixels SP. The light-emitting area EA of each of the plurality of subpixels SP, which is disposed in the opening area of the bank 116, may be disposed to be spaced apart from the first bank 116a and the second bank 116b and surrounded by the first bank 116a and the second bank 116b. That is, the bank 116 has a non-opening area and an opening area, and the non-opening area includes a full-tone bank area 116a and a halftone bank area 116b. The opening area of the bank may be the light-emitting area EA of each of the plurality of subpixels SP, and the halftone bank area 116b may be the second non-light-emitting area NEA2 and disposed between the light-emitting areas EA. The full-tone bank area 116a may correspond to the first non-light-emitting area NEA1.

For example, in case that the plurality of subpixels SP is disposed in a stripe manner as illustrated in FIG. 2B, the plurality of subpixels SP may be arranged in one direction in a plan view, and the light-emitting area EA of each of the plurality of subpixels SP may have a shape extending in a second direction intersecting one direction. In this case, the second bank 116b may be disposed between the light-emitting areas EA of the plurality of subpixels SP and disposed in a shape extending in the second direction. Further, the first banks 116a may be connected to the second banks 116b and disposed above and below the second banks 116b and the light-emitting areas EA of the plurality of subpixels SP arranged in one direction. However, the present disclosure is not limited thereto.

Meanwhile, the light-emitting element 130 may be disposed in the opening area of the bank 116 corresponding to each of the light-emitting areas EA. The first electrode 131 of the light-emitting element 130 may be disposed in the opening area of the bank 116. In this case, the bank 116 may be disposed to be spaced apart from the first electrode 131 disposed in the light-emitting area EA of each of the plurality of subpixels SP.

Specifically, with reference to FIG. 3, the second bank 116b is disposed to expose the first electrode 131. The second bank 116b is disposed to be spaced apart from the first electrode 131. The second bank 116b is not disposed on the first electrode 131. The second bank 116b may be disposed so as not to cover the first electrode 131. In this case, the second bank 116b may be disposed below the first electrode 131. For example, during the process of manufacturing the display device 100, the second bank 116b may be disposed after a process of disposing the first electrode 131 is performed. However, the second bank 116b may be disposed below the first electrode 131 because the second bank 116b is disposed in the groove 115H of the overcoating layer 115 and is disposed to have a smaller thickness than the first bank 116a.

The organic layer 132 is disposed on the first electrode 131 and the second bank 116b. For example, the organic layer 132 may be disposed on the first electrode 131 in the light-emitting area EA. The organic layer 132 may be disposed on the second bank 116b in the second non-light-emitting area NEA2 and disposed in the groove. The organic layer 132 may be disposed along a shape of the first electrode 131 and a shape of the second bank 116b. The organic layer 132 includes a light-emitting layer and a common layer.

The light-emitting layer is an organic layer configured to emit light with a particular color. Different light-emitting layers may be disposed in the plurality of subpixels SP, respectively. The identical light-emitting layers may be disposed in the entire plurality of subpixels SP. For example, in the case in which the different light-emitting layers are disposed in the plurality of subpixels SP, respectively, a red light-emitting layer may be disposed in the red subpixel SPR, a green light-emitting layer may be disposed in the green subpixel SPG, and a blue light-emitting layer may be disposed in the blue subpixel SPB. In the case in which the identical light-emitting layers are disposed in the entire plurality of subpixels SP, the light emitted from the light-emitting layer may be converted into the light with various colors by a separate optical conversion layer, a color filter, or the like.

The common layer is an organic layer disposed to improve luminous efficiency of the light-emitting layer. The identical common layers may be formed over the plurality of subpixels SP. That is, the common layers of the plurality of subpixels SP may be made of the same material and simultaneously formed through the same process. The common layer may include a positive hole injecting layer, a positive hole transporting layer, an electron transporting layer, an electron injecting layer, a charge generating layer, and the like. However, the present disclosure is not limited thereto.

Meanwhile, the organic layer 132 may be configured by stacking a plurality of light-emitting parts each including the light-emitting layer and configured to emit light. For example, the light-emitting parts each include a hole injection layer, a hole transport layer, a light-emitting layer, an electron transport layer, and an electron injection layer. A charge generating layer configured to supply charges to the plurality of light-emitting parts is disposed between the adjacent light-emitting parts. Therefore, the organic layer 132 may emit lights in which the lights emitted from the plurality of light-emitting parts are mixed. However, the present disclosure is not limited thereto.

The second electrode 133 is disposed on the organic layer 132. The second electrode 133 is disposed on the organic layer 132 and overlaps the first electrode 131 and the groove 115H. The second electrode 133 may be disposed along a shape of the organic layer 132. Because the second electrode 133 supplies the electrons to the organic layer 132, the second electrode 133 may be made of an electrically conductive material with a low work function. The second electrode 133 may be a cathode of the light-emitting element 130. Because the organic light-emitting display device 100 of the embodiment of the present disclosure is a bottom-emission type display device, a cathode 156 may be made of a metallic material with high reflectance to allow the light emitted from an organic light-emitting element 150 to propagate toward a lower side of the glass substrate 110. For example, the cathode 156 may be made of a metallic material selected from calcium (Ca), barium (Ba), aluminum (Al), silver (Ag), and an alloy containing one or more of the above-mentioned elements. However, the present disclosure is not limited thereto. Meanwhile, although not illustrated in the drawings, the second electrode 133 may be electrically connected to a low-potential power line and supplied with a low-potential power signal.

Meanwhile, although not illustrated in the drawings, an encapsulation part and an encapsulation substrate may be further disposed above the light-emitting element 130.

The encapsulation part may be disposed on the light-emitting element 130. The encapsulation part may protect the light-emitting element 130 vulnerable to moisture so that the light-emitting element 130 is not exposed to moisture. The encapsulation part may inhibit oxygen and moisture from penetrating into the display device 100 from the outside. For example, in case that the display device 100 is exposed to moisture or oxygen, a pixel contraction phenomenon in which the light-emitting area is contracted may occur, or a problem in which a black spot occurs in the light-emitting area may occur. Therefore, the encapsulation part protects the display device 100 by blocking oxygen and moisture. For example, the encapsulation part may have a structure in which the inorganic layer and the organic layer are alternately stacked. However, the present disclosure is not limited thereto.

The encapsulation substrate may be disposed on the encapsulation part. The encapsulation substrate, together with the encapsulation part, protects the light-emitting element 130 from outside moisture, oxygen, impact, and the like. The encapsulation substrate may be made of a metallic material such as stainless steel (SUS) or a plastic material such as polymethylmethacrylate, polycarbonate, polyvinyl alcohol, acrylonitrile-butadiene-styrene, or polyethylene terephthalate.

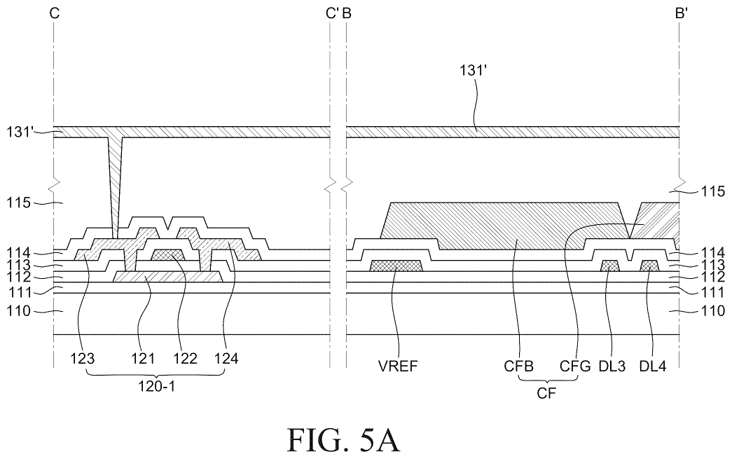

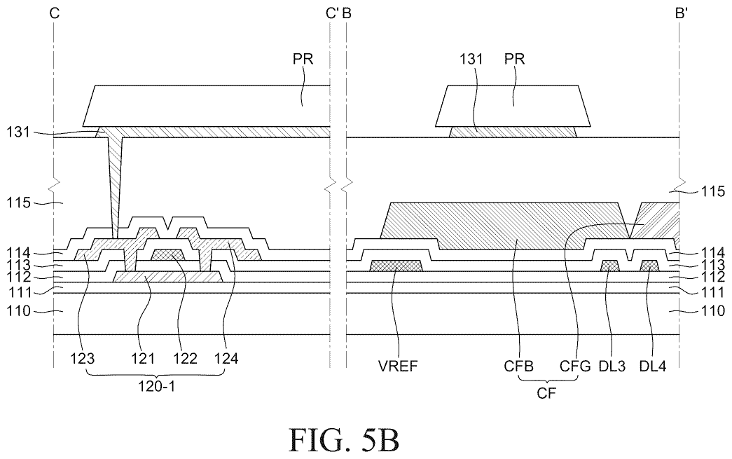

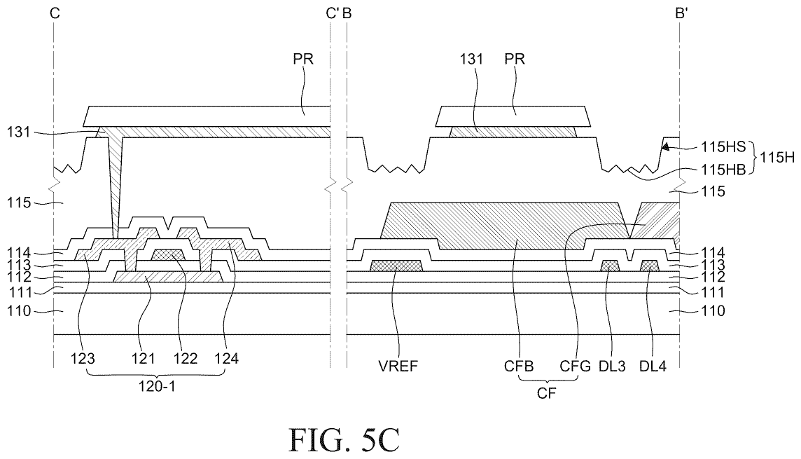

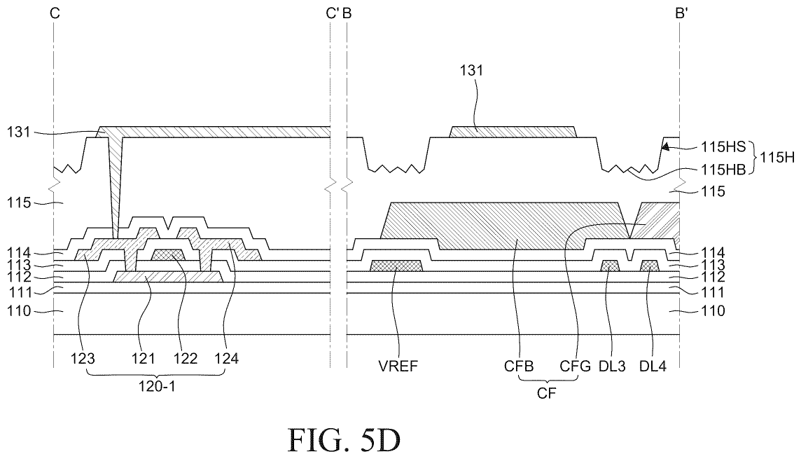

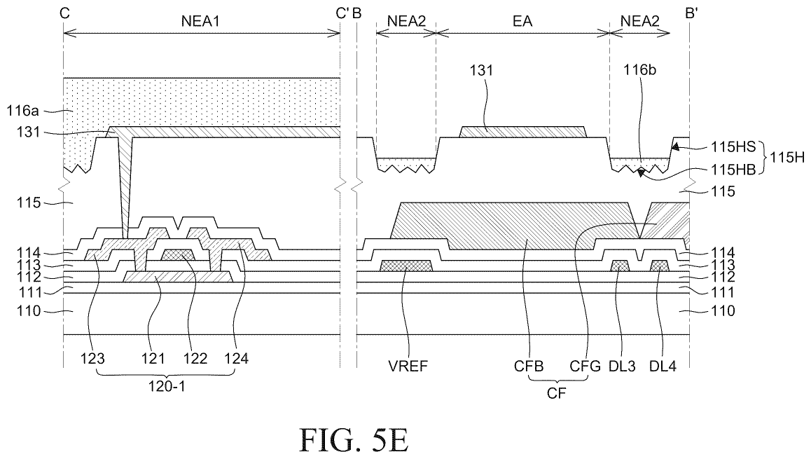

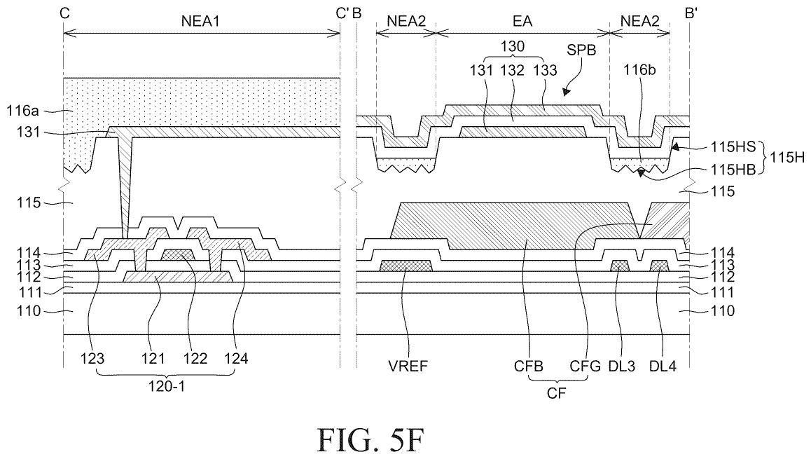

Hereinafter, a process of manufacturing the display device according to the embodiment of the present disclosure will be described in detail with reference to FIGS. 5A to 5F.

FIGS. 5A to 5F are process flowcharts for explaining a process of manufacturing the display device according to an embodiment of the present specification.

With reference to FIG. 5A, the first transistor 120-1 is disposed in the first non-light-emitting area NEA1 on the substrate 110, and the color filter CF is formed in the light-emitting area EA. The overcoating layer 115 is formed above the first transistor 120-1 and the color filter CF and planarizes the upper portion of the first transistor 120-1 and the upper portion of the color filter CF. Further, the contact hole, through which the source electrode 123 of the first transistor 120-1 is exposed, is formed in the overcoating layer 115. A material 131′ for forming the first electrode 131 is disposed on the overcoating layer 115.

Next, with reference to FIG. 5B, a photoresist PR is patterned on the material 131′ for forming the first electrode 131, and then the material 131′ for forming the first electrode 131 exposed from the photoresist PR is etched and removed, such that the first electrode 131 is formed. In this case, for example, a method of etching the material for forming the first electrode 131′ may use a wet etching method or the like. However, the present disclosure is not limited thereto.

Next, with reference to FIG. 5C, the groove 115H is formed by performing ashing on the surface of the overcoating layer 115 exposed from the first electrode 131 and the photoresist PR. In this case, in order to ensure the space in which the organic layer 132 and the second electrode 133 are disposed, the groove 115H may include the side surface 115HS with an inclined shape, and the bottom surface 115HB surrounded by the side surface 115HS. In this case, because the ashing condition with high straightness needs to be applied to form the bottom surface 115HB, the surface of the bottom surface 115HB may have a shape having a concave-convex portion.

Further, with reference to FIG. 5D, the photoresist PR remaining above the first electrode 131 is removed by a stripping process. Therefore, the first electrode 131 may be disposed to be spaced apart from the groove 115H of the overcoating layer 115.

Next, with reference to FIG. 5E, the bank 116 is formed on the overcoating layer 115. Specifically, the first bank 116a is disposed in the first non-light-emitting area NEA1 on the overcoating layer 115, and the second bank 116b is formed in the groove 115H corresponding to the second non-light-emitting area NEA2. The first bank 116a and the second bank 116b may be simultaneously formed and made of the same material. Therefore, no interface may be formed between the first bank 116a and the second bank 116b. For example, the first bank 116a and the second bank 116b may be simultaneously formed and made of the same material by using a halftone mask and disposed with different thicknesses. However, the present disclosure is not limited thereto.

Lastly, with reference to FIG. 5F, the organic layer 132 and the second electrode 133 are formed on the first electrode 131. In this case, the organic layer 132 and the second electrode 133 are disposed to overlap the groove 115H. Therefore, the second electrode 133 may be configured to reflect the light, which is emitted from the organic layer 132, toward the lower side of the display device 100.

Meanwhile, although not illustrated, various constituent elements, such as the encapsulation part and the encapsulation substrate, may be further disposed above the second electrode 133. Therefore, the process of manufacturing the display device 100 may be completed.

In the bottom-emission type display device, i.e., the display device in which the groove, which surrounds the side surface of the first electrode, is disposed in the overcoating layer and the organic layer and the second electrode are disposed in the groove, the lights, which are emitted toward the lateral portion of the light-emitting element among the lights emitted from the organic layer, may be reflected by the second electrode disposed in the groove, and the lights may be extracted to the outside of the display device, which may improve the light extraction efficiency of the display device.

However, because the ashing condition with high straightness may be used to form the groove during the process of forming the groove in the overcoating layer, an irregular concave-convex shape may be formed on the surface of the groove. In particular, the irregular concave-convex shape is a position deepest in the groove, and the irregularity is greater in the bottom surface of the groove to which the ashing is applied for the longest period of time more.

In this case, because the bottom surface of the groove is an area adjacent to the constituent elements, such as the color filter, for example, disposed below the overcoating layer, the constituent elements disposed below the overcoating layer are exposed from the overcoating layer by the irregular concave-convex portion, which may cause a problem in that moisture penetrates into the constituent elements of the display device.

In addition, the organic layer and the second electrode disposed in the groove may also be disposed to have irregular thicknesses along the surface of the groove having the irregular concave-convex shape. Therefore, the second electrode may be cracked by the irregular thicknesses of the organic layer and the second electrode, and moisture may penetrate into the constituent elements of the display device through the crack in the second electrode.

Therefore, in the display device 100 according to the embodiment of the present disclosure, the second bank 116b is disposed in the groove 115H of the overcoating layer 115, which may mitigate the concave-convex shape of the bottom surface 115HB of the groove 115H.

Specifically, in the display device 100 according to the embodiment of the present disclosure, the overcoating layer 115 includes the groove 115H disposed along the outer periphery of the light-emitting area EA of each of the plurality of subpixels SP. The groove 115H includes the side surface 115HS having an inclination, and the bottom surface 115HB surrounded by the side surface 115HS. In this case, the bottom surface 115HB of the groove 115H may have a shape having the concave-convex portion formed on the surface thereof. The second bank 116b is disposed in the groove 115H. Therefore, the second bank 116b may cover the shape with the concave-convex portion of the bottom surface 115HB of the groove 115H. That is, the roughness of a bottom surface of the second bank 116b, which corresponds to the concave-convex shape of the bottom surface 115HB of the groove 115H, may be higher than the roughness of a top surface of the second bank 116b. Therefore, the second bank 116b may mitigate the concave-convex shape of the bottom surface 115HB and minimize a degree to which the components disposed below the overcoating layer 115 from being exposed from the overcoating layer 115. In addition, the second bank 116b mitigates the concave-convex shape of the bottom surface 115HB, the organic layer 132 and the second electrode 133 are uniformly disposed in the groove 115H, which may minimize the occurrence of cracks in the second electrode. Therefore, it is possible to minimize a moisture penetration defect caused when the components disposed below the overcoating layer 115 are exposed from the overcoating layer 115 or the second electrode cracks. Further, it is possible to solve the problem of deterioration in reliability of the display device. Therefore, in the display device 100 according to the embodiment of the present disclosure, the second bank 116b is disposed in the groove 115H of the overcoating layer 115, which may mitigate the concave-convex shape of the bottom surface 115HB of the groove 115H and improve the reliability of the display device.

Meanwhile, the second bank 116b may expose the upper side of the side surface 115HS of the groove 115H. Therefore, the organic layer 132 and the second electrode 133 may be disposed on the side surface 115HS of the groove 115H exposed from the second bank 116b, and the second electrode 133 may not hinder the function of reflecting the light emitted from the organic layer 132.

The exemplary embodiments of the present disclosure can also be described as follows:

A display device according to an embodiment of the present disclosure includes: a substrate on which a plurality of subpixels each including a light-emitting area and a non-light-emitting area configured to surround the light-emitting area is disposed; a transistor disposed in the non-light-emitting area on the substrate; an overcoating layer disposed in the light-emitting area and the non-light-emitting area on the transistor and including a groove disposed in the non-light-emitting area along an outer periphery of the light-emitting area; a first electrode disposed in the light-emitting area on the overcoating layer; a bank disposed in the non-light-emitting area on the overcoating layer and disposed to be spaced apart from the first electrode; an organic layer disposed on the first electrode and the bank; and a second electrode disposed on the organic layer and configured to overlap the first electrode and the groove, in which a thickness of the bank disposed in the groove on the overcoating layer is smaller than a thickness of the bank disposed in the remaining part.

A side surface of the groove may have an inclination.

The groove may comprise a bottom surface surrounded by the side surface of the groove, and the bank may be disposed on the bottom surface of the groove.

The bottom surface may have a concave-convex portion.

A part of an upper side of the side surface of the groove may be exposed from the bank.

The display device may further comprise a color filter disposed between the substrate and the overcoating layer while corresponding to the light-emitting area.

The color filter may be disposed on the substrate and spaced apart from the transistor.

The plurality of subpixels may be arranged in one direction and configured to emit lights of different colors, and the grooves may be respectively disposed at two opposite sides of the plurality of subpixels.

The bank disposed in the groove on the overcoating layer and the bank disposed in the remaining part may be connected with each other with no interface formed therebetween.

A display device according to another embodiment of the present disclosure includes: a substrate on which a plurality of subpixels each including a light-emitting area is disposed; an overcoating layer disposed on the substrate and including a groove disposed along an outer periphery of a light-emitting area of each of the plurality of subpixels; a first electrode disposed in the light-emitting area on the overcoating layer; a bank including a first bank disposed on the overcoating layer and spaced apart from the first electrode, and a second bank disposed in the groove and having a smaller thickness than the first bank; an organic layer disposed on the first electrode and the bank; and a second electrode disposed on the organic layer and configured to overlap the first electrode and the groove.

A side surface of the groove may be inclined.

The groove may comprise a bottom surface surrounded by the inclined side surface of the groove, and the second bank may be disposed on the bottom surface and a part of the side surface of the groove.

The bottom surface may have a concave-convex.

An upper side of the side surface of the groove may be exposed from the second bank.

The display device may further comprise a transistor disposed between the substrate and the overcoating layer in each of the plurality of subpixels, and a color filter disposed to correspond to the light-emitting area of each of the plurality of subpixels and spaced apart from the transistor.

The subpixels, which emit lights of different colors among the plurality of subpixels, may be arranged in one direction, and the grooves may be respectively disposed at two opposite sides of the plurality of subpixels.

No interface is formed between the first bank and the second bank.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate on which a plurality of subpixels are disposed, each of the plurality of subpixels comprising a light-emitting area and a non-light-emitting area that surrounds the light-emitting area;
a transistor in the non-light-emitting area on the substrate;
an overcoating layer in the light-emitting area, the non-light-emitting area, and on the transistor, the overcoating layer comprising a groove in the non-light-emitting area along an outer periphery of the light-emitting area;
a first electrode in the light-emitting area on the overcoating layer;
a bank disposed in the non-light-emitting area on the overcoating layer, the bank spaced apart from the first electrode;
an organic layer on the first electrode and the bank; and
a second electrode on the organic layer, the second electrode overlapping the first electrode and the groove,
wherein a thickness of the bank in the groove on the overcoating layer is smaller than a thickness of the bank in a remaining part.

2. The display device of claim 1, wherein a side surface of the groove has an inclination.

3. The display device of claim 2, wherein the groove comprises a bottom surface surrounded by the side surface of the groove, and the bank is on the bottom surface of the groove.

4. The display device of claim 3, wherein the bottom surface has a concave-convex portion.

5. The display device of claim 2, wherein a part of an upper side of the side surface of the groove is exposed from the bank.

6. The display device of claim 1, further comprising:
a color filter between the substrate and the overcoating layer, the color filter corresponding to the light-emitting area,
wherein the color filter is on the substrate and spaced apart from the transistor.

7. The display device of claim 1, wherein the plurality of subpixels are arranged in one direction and configured to emit light of different colors, and grooves are respectively disposed at two opposite sides of the plurality of subpixels.

8. The display device of claim 1, wherein the bank disposed in the groove on the overcoating layer and the bank disposed in the remaining part are connected with each other with no interface formed therebetween.

9. A display device comprising:
a substrate on which a plurality of subpixels are disposed, each of the plurality of subpixels comprising a light-emitting area;
an overcoating layer on the substrate, the overcoating layer comprising a groove along an outer periphery of the light-emitting area of each of the plurality of subpixels;
a first electrode in the light-emitting area on the overcoating layer;
a bank comprising a first bank on the overcoating layer and spaced apart from the first electrode and a second bank in the groove and having a smaller thickness than the first bank;
an organic layer on the first electrode and the bank; and
a second electrode on the organic layer, the second electrode overlapping the first electrode and the groove.

10. The display device of claim 9, wherein a side surface of the groove is inclined.

11. The display device of claim 10, wherein the groove comprises a bottom surface surrounded by the inclined side surface of the groove, and the second bank is on the bottom surface and a part of the side surface of the groove.

12. The display device of claim 11, wherein the bottom surface has a concave-convex portion present on a surface thereof.

13. The display device of claim 10, wherein an upper side of the side surface of the groove is exposed from the second bank.

14. The display device of claim 9, further comprising:
a transistor between the substrate and the overcoating layer in each of the plurality of subpixels; and
a color filter corresponding to the light-emitting area of each of the plurality of subpixels and spaced apart from the transistor.

15. The display device of claim 9, wherein subpixels, which emit light of different colors among the plurality of subpixels, are arranged in one direction, and grooves are respectively disposed at two opposite sides of the plurality of subpixels.

16. The display device of claim 9, wherein no interface is between the first bank and the second bank.
